(19) United States
(12) Patent Application Publication
(10) Pub. No.: US 2007/0103954 A1
(43) Pub. Date: May 10, 2007

(54) Memory circuit

(76) Inventor: Yuuichirou Ikeda, Hyogo (JP)

Correspondence Address: MCDERMOTT WILL & EMERY LLP, 600 13TH STREET, N.W., WASHINGTON, DC, 20005-3096, US

(21) Appl. No.: 11/590,803

(22) Filed: Nov. 1, 2006

(30) Foreign Application Priority Data
Nov. 4, 2005 (JP) 2005-320616

(51) Int. Cl. G11C 5/02

(52) U.S. Cl. 365/51

(57) ABSTRACT

There is provided a memory circuit including a first memory cell mapped on an address space accessible from a processor, and a second memory cell not mapped on the address space and having the same constitution as that of the first memory cell, wherein a control circuit for executing a control function relating to the memory circuit is included, and an output signal line of the second memory cell is connected to the control circuit.

### BACKGROUND OF THE INVENTION

1. Field of the Invention

The present invention relates to a memory circuit equipped with a replica memory cell for operation timing generation or process compensation.

2. Description of the Related Art

In a macro memory and a SRAM (Static Random Access Memory) such as a register file for temporarily preserving data such as a calculation result and an address required for a memory access, it is effective to control a power supply voltage and a substrate voltage to reduce power consumption. When such a control is conducted, a control value needs to be set. However, conventionally, as illustrated in “An Autonomous Denetralized Low-Power System with Adaptive-Universal Control for a Chip Multi-Processor”, ISSCC2003 Paper 6.4 (FIG. 6.4.1), this control value is set by using a storage circuit provided outside the macro memory.

Storage circuits such as a flip-flop required for controlling the power supply voltage and the substrate voltage increase the number thereof in accordance with an object to be controlled and the number of states. Therefore, in a case of a plurality of controlled objects and number-of states, a circuit area is increased.

### SUMMARY OF THE INVENTION

Accordingly, a main object of the present invention is to reduce the number of storage circuits separately required for control, thereby reducing a circuit area.

In order to solve the above-described problem, a replica memory cell for operation timing generation and process compensation is mounted on a memory circuit of the present invention. Although the replica memory cell cannot be used as a normal memory during normal operation, it is capable of storing various information according to a purpose of use. According to the present invention, the storage circuit for control is reduced, which is separately required in the conventional art, by storing a control value in the replica memory cell and generating a control signal based on the control value. Note that according to the present invention, a memory cell corresponding to the replica memory cell is expressed as “a second memory cell”.

The memory circuit of the present invention includes

a first memory cell mapped on an address space accessible from a processor,

a second memory cell not mapped on the address space and having a same constitution as that of the first memory cell, and

a control circuit for executing a control function relating to the memory circuit,

wherein an output signal line of the second memory cell is connected to the control circuit.

In addition, a timing generating circuit is further provided, and preferably,

the control circuit executes the control function different from an access timing control executed by the timing generating circuit, and

the timing generating circuit generates an access timing to the first memory cell by referring to a value acquired from the second memory cell.

According to the aforementioned constitution of the present invention, the first memory cell corresponds to the memory cell of a normal use form, and the second memory cell corresponds to the replica memory cell. According to the conventional art, the second memory cell is used for replicating (copying/reproducing) a load of a bit line or a word line to the first memory cell, and information stored in the second memory cell is not used (referred). Meanwhile, according to the present invention, the output signal line of the second memory cell is connected to the control circuit executing the control function (control of such as a processor and memory circuit) relating to the memory circuit. Thus, the value stored in the second memory cell can be used (referred) by the control circuit. As a result, the storage circuit for control such as a flip-flop, which is conventionally required, needs not to be separately provided, thus making it possible to reduce the circuit area.

Preferably, the second memory cell is provided for compensating a characteristic fluctuation of the first memory cell. In the aforementioned constitution, the second memory cell is not provided for timing generation but provided for process compensation, and the timing generating circuit is not required. Therefore, by connecting the output signal line of the second memory cell to the control circuit, the value stored in the second memory cell can be used in the control circuit. As a result, the storage circuit for control such as the flip-flop, which is conventionally required, needs not to be separately provided, thus making it possible to reduce the circuit area.

In addition, the control circuit can take various forms in accordance with a controlled object and control content as follows. Namely, in a first aspect, a value relating to control of the processor is recorded in the second memory cell, and the control circuit controls the processor by referring to the value in the second memory cell. According to this aspect, the storage circuit for controlling the processor, which is required within the processor in the conventional art, is not required, and the circuit area can thereby be reduced.

In a second aspect, a value relating to internal control of the memory circuit is recorded in the second memory cell, and the control circuit performs internal control of the memory circuit by referring to the value in the second memory cell. According to this aspect, the storage circuit for controlling the memory circuit, which is required in the conventional art, is not required, and the circuit area can thereby be reduced. Also, by performing control within the memory circuit, the load of the processor can be reduced.

In a third aspect, a value relating to the power supply voltage of the memory circuit is recorded in the second memory cell, and the control circuit controls the power supply voltage of the memory circuit by referring to the value in the second memory cell. According to this aspect, by controlling the power supply voltage, power consumption can be further reduced and an operation speed can be further increased.

In a fourth aspect, a value relating to the substrate voltage of the memory circuit is recorded in the second memory cell, and the control circuit controls the substrate voltage of the memory circuit by referring to the value in the second memory cell. According to this aspect, by controlling the substrate voltage, the power consumption can be further reduced and the operation speed can be further increased.

In a fifth aspect, a value relating to an operation frequency of the memory circuit is recorded in the second memory cell, and the control circuit controls the operation frequency of the memory circuit by referring to the value in the second memory cell. According to this aspect, by controlling the operation frequency, the power consumption can be further reduced and the operation speed can be further increased.

In a sixth aspect, a value relating to control of a port access of the memory circuit is recorded in the second memory cell, and the control circuit controls the port access of the memory circuit by referring to the value in the second memory cell. According to this aspect, by controlling the port access of the memory circuit, the power consumption can be further reduced and the operation speed can be further increased. In addition, by performing control within the memory circuit, the load of the processor can be reduced.

In a seventh aspect, a value relating to timing adjustment of an input/output signal to/from the memory circuit is recorded in the second memory cell, and the control circuit performs the timing adjustment of the input/output signal to/from the memory circuit by referring to the value in the second memory cell. According to this aspect, by performing the timing adjustment of the input/output to/from the memory circuit, setting-up, hold, and access time, etc, of the memory circuit can be further optimized.

In an eighth aspect, a value relating to timing correction of an internal signal of the memory circuit is recorded in the second memory cell, and the control circuit performs the timing correction of the internal signal of the memory circuit by referring to the value in the second memory cell. According to this aspect, by performing the timing correction of the internal signal of the memory circuit, an influence on the operation speed due to drop of the power supply voltage can be further suppressed.

In a ninth aspect, there is further provided a cross talk suppressing circuit for suppressing cross talk within the memory circuit, a value relating to suppression of the cross talk within the memory circuit is recorded in the second memory cell, and the control circuit controls the cross talk suppressing circuit by referring to the value in the second memory cell. According to this aspect, by controlling the cross talk suppressing circuit of the memory circuit, the power consumption can be further reduced and the operation speed can be further increased. In addition, by performing the control within the memory circuit, the load of the processor can be reduced.

In a tenth aspect, the control circuit is disposed in an empty region close to the second memory cell within the memory circuit. According to this aspect, by disposing the control circuit in an originally empty region, the circuit area can be further reduced.

In an eleventh aspect, the output signal line is constituted of a bit line of the memory circuit. According to this aspect, by using the bit line of the memory circuit, the circuit area can be reduced.

In a twelfth aspect, the output signal line is constituted of a wire different from the bit line of the memory circuit. According to this aspect, by providing the output signal line separately from the bit line of the memory circuit, the control of the output signal line is not required, thus making it easy to design.

In a thirteenth aspect, the processor sets a value to be written in the second memory cell. According to this aspect, by setting the aforementioned value by the processor, the circuit area of the memory circuit can be further reduced. In addition, an arbitrary value can be set by the processor.

In a fourteenth aspect, a written value setting circuit is further provided for setting the value to be written in the second memory cell. According to this aspect, the value to be written in the second memory cell can be arbitrarily set, and an arbitrary one can be selected from a plurality of control states.

In a fifteenth aspect, the written value setting circuit is disposed in the empty region close to the second memory cell within the memory circuit. According to this aspect, by disposing the written value setting circuit in an originally empty region, the circuit area can be further reduced.

In a sixteenth aspect, the written value setting circuit sets the value based on the internal state of the memory circuit. According to this aspect, by generating the aforementioned value in accordance with a state within the memory circuit, the value in accordance with the operation of the memory circuit can be set, and self-correcting control of the memory circuit is enabled.

In a seventeenth aspect, the written value setting circuit sets the value based on the operation speed of the memory circuit. According to this aspect, by setting the written value in accordance with the operation speed of the memory circuit, the control in accordance with the operation speed of the memory circuit is enabled, and the power consumption can be reduced.

In an eighteenth aspect, the written value setting circuit sets the aforementioned value based on an internal voltage of the memory circuit. According to this aspect, by setting the written value based on the internal voltage of the memory circuit, the control in accordance with a voltage state of the memory circuit is enabled, and the drop of the power supply voltage is compensated.

In a nineteenth aspect, the written value setting circuit sets the value based on a cross talk amount of a signal line of the memory circuit. According to this aspect, by setting the written value in accordance with the cross talk amount of the signal line within the memory circuit, the control in accordance with the cross talk amount of the signal line of the memory circuit is enabled, and deterioration of the operation speed due to the cross talk suppressing circuit is suppressed, and the cross talk amount can be reduced.

According to the present invention, by storing the control value in the second memory cell corresponding to the replica memory cell, and generating the control signal based on the control value, the storage circuit for control, which is separately required in the conventional art, can be reduced, and the circuit area can thereby be reduced. In addition, by using the control value in controlling the power supply voltage, the substrate voltage, and the operation speed, the power consumption by the processor and the memory circuit can be reduced, and the operation speed can be increased.

The memory circuit of the present invention is useful as a technique of realizing the power consumption reduction and high-speed operation of the macro memory such as the SRAM and register file, while reducing the circuit area.

### BRIEF DESCRIPTION OF THE DRAWINGS

Objects of the present invention other than those described above will be clarified by understanding embodiments as will be explained hereunder which are specifically indicated by appended claims, and various advantages not described in this specification would be revealed by persons skilled in the art by executing the present invention.

FIG. 1 is a block diagram showing a constitution of a memory circuit according to an embodiment 1 of the present invention;

FIG. 2 is a first circuit constitutional view of a second memory cell according to the embodiment 1 of the present invention;

FIG. 3 is a second circuit constitutional view of the second memory cell according to the embodiment 1 of the present invention;

FIG. 4 is a block diagram showing the constitution of the memory circuit according to an embodiment 2 of the present invention;

FIG. 5 is a block diagram showing the constitution of the memory circuit according to an embodiment 3 of the present invention;

FIG. 6 is a block diagram showing the constitution of the memory circuit according to an embodiment 4 of the present invention;

FIG. 7 is a circuit constitutional view of a written value setting circuit according to the embodiment 4 of the present invention; and

FIG. 8 is a circuit constitutional view of the written value setting circuit according to the embodiment 4 of the present invention.

### DETAILED DESCRIPTION OF THE INVENTION

Hereunder, embodiments of a memory circuit according to the present invention will be explained in detail based on the drawings.

(Embodiment 1)

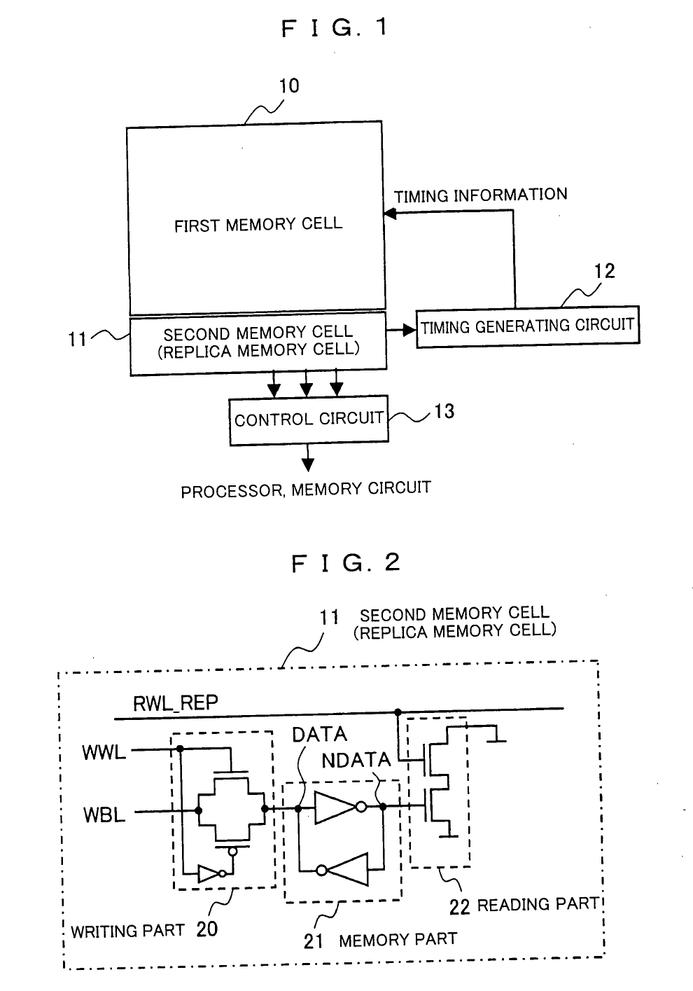

FIG. 1 is a block diagram showing a constitution of a memory 15 circuit according to an embodiment 1 of the present invention. In the diagram, a memory cell as a storage holding circuit and its peripheral circuits are shown. In FIG. 1, designation numeral “10” indicates a first memory cell, designation numeral “11” indicates a second memory cell, designation numeral “12” indicates a timing generating circuit, and designation numeral “13” indicates a control circuit. The first memory cell 10 is a memory cell simple body or a memory cell in an array configuration mapped on an address space accessible from a processor unit.

The second memory cell 11 is not mapped on the address space, and is a memory cell simple body or a memory cell in an array configuration having the same constitution as that of the first memory cell 10. The timing generating circuit 12 generates an access timing for either or the both of reading/writing from/in the first memory cell 10, by referring to information in the second memory cell 11. The control circuit 13 has a prescribed control function different from that of the timing generating circuit 12. The second memory cell 11 corresponds to a replica memory cell.

When the second memory cell 11 is used for timing generation, its output signal line is connected to the timing generating circuit 12, and by using a voltage transition of the output signal line, the timing of writing operation and reading operation in/from the first memory cell 10 is generated. On the other hand, in the conventional constitution, most of the second memory cell 11 is used for replicating a load of a bit line or a word line, and the information stored in a memory part in the second memory cell 11 is not used.

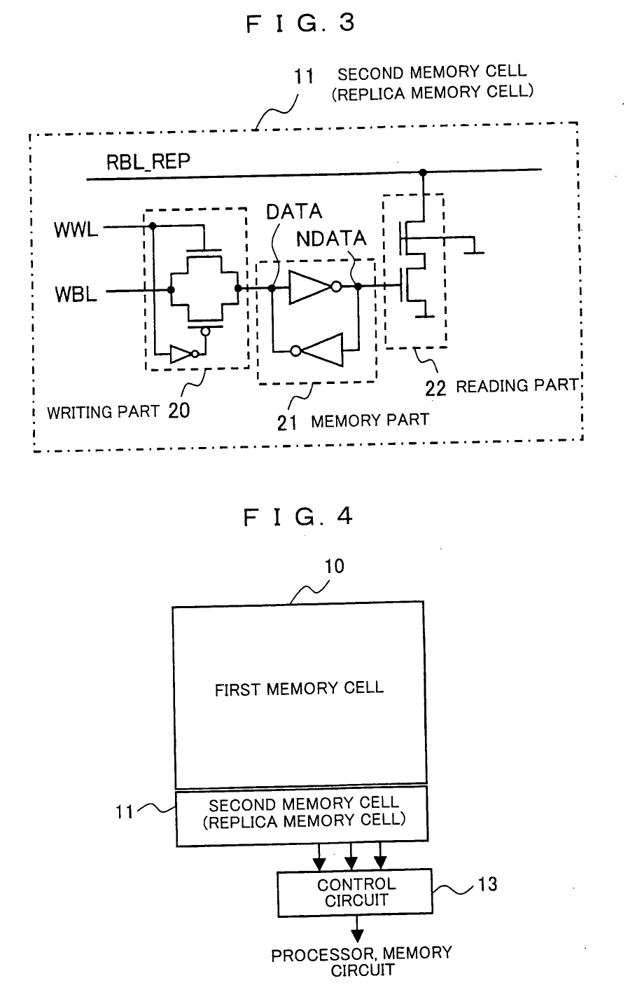

FIG. 2 and FIG. 3 show specific examples of the second memory cell 11, which is the replica memory cell. For example, FIG. 2 is an example of the replica memory cell of a read word line, and FIG. 3 is an example of the replica memory cell of a read bit line. Data written in a DATA line of a memory part 21 is not used. Note that the replica memory cell having a different constitution of a writing part 20, a memory part 21, and a reading part 22 is also applicable as the second memory cell 11. WWL is a write word line, WBL is a write bit line, RWL_REP is a read replica word line, DATA is memory part holding data, NDATA is memory part reversing support data, and RBL_REP is a read replica bit line.

In this embodiment, such a second memory cell 11 connects the output signal line thereof to the control circuit 13. The control circuit 13 has a prescribed control function for controlling the processor and the memory circuit separately from the timing generating circuit 12. In this embodiment, by connecting the output signal line to the control circuit 13 having such a function, the information stored in the memory part 21 of the second memory cell 11 can be used by the control circuit 13. For example, by directly connecting the DATA line and NDATA line of the second memory cell 11 as shown in FIG. 2 and FIG. 3 to the control circuit 13, or by connecting the second memory cell 11 to the control circuit 13 through a reading circuit not used in a case of a multiported memory, the information stored in the memory part 21 of the second memory cell 11 can be used (referred) by the control circuit 13.

According to this embodiment, the storage circuit such as a flip-flop connected to the control circuit 13 is not required, and the circuit area can thereby be reduced.

(Embodiment 2)

FIG. 4 is a block diagram showing a constitution of the memory circuit in an embodiment 2 of the present invention. Differently from FIG. 1, the second memory cell 11 is not used for timing generation, but is provided for process compensation. In this memory circuit, the timing generating circuit 12 as shown in FIG. 1 does not exist. Conventionally, the output signal line of the second memory cell 11 is set in a floating state or a fixed state, and the value stored in the memory part (same as the memory part 21 of FIG. 1) of the second memory cell 11 is not used. In this embodiment, by connecting the output signal line to the control circuit 13, the value stored in the aforementioned memory part can be used (referred) by the control circuit 13. Thus, the storage circuit such as the flip-flop connected to the control circuit 13 is not required, and the circuit area can thereby be reduced.

The control circuit 13 can take various forms in accordance with the controlled object and the control content. Hereunder, the control circuit 13 will be specifically described. In this constitution, the control circuit 13 is capable of controlling the processor by using (referring) the value stored in the second memory cell 11. In this case, the storage circuit such as the flip-flop connected to the control circuit 13 needs not to be provided in the processor, and an occupied area of the processor can be reduced.

When the control circuit 13 controls a power supply voltage of the processor, by referring to the value in the second memory cell 11 after the value relating to the control of the power supply voltage of the processor is recorded in the second memory cell 11, the power consumption of the entire processor can be reduced by lowering the power supply voltage. Meanwhile, by increasing the power supply voltage, the operation speed of the entire processor can be increased.

Also, when the control circuit 13 controls the power supply voltage of the memory circuit by referring to the value in the second memory cell 11 after the value relating to the control of the power supply voltage of the memory circuit is recorded in the second memory cell 11, by lowering the power supply voltage, the power consumption of the memory circuit can be reduced. Meanwhile, by increasing the power supply voltage, the operation speed of the memory circuit can be increased.

Also, when the control circuit 13 controls the substrate voltage of the processor by referring to the value in the second memory cell 11 after the value relating to the control of the substrate voltage of the processor is recorded in the second memory cell 11, the power consumption of the entire processor can be reduced by applying back bias for increasing a threshold value voltage to a substrate. Meanwhile, the operation speed of the entire processor can be increased by applying forward bias for reducing the threshold value voltage to the substrate.

When the control circuit 13 controls the power supply voltage of the memory circuit by referring to the value in the second memory cell 11 after the value relating to the control of the power supply voltage of the memory circuit is recorded in the second memory cell, the power consumption of the memory circuit can be reduced by applying the back bias to the substrate on which the memory circuit is mounted. Meanwhile, the operation speed of the memory circuit can be increased by applying the forward bias to the substrate.

When the control circuit 13 controls an operation frequency of the processor by referring to the value in the second memory cell 11 after the value relating the control of the operation frequency of the processor is recorded in the second memory cell 11, the power consumption of the entire processor can be reduced by lowering the operation frequency. Meanwhile, the operation speed of the entire processor can be increased by increasing the operation frequency.

Also, when the memory circuit is multiported, the control circuit 13 performs an access control of ports by referring to the value in the second memory cell 11 after the value relating to the control of the port access of the memory circuit is recorded in the second memory cell 11 the access to the port whose operation is unnecessary can be stopped, thus making it possible to reduce the power consumption.

Also, the control circuit 13 is also capable of controlling the memory circuit by referring to the value in the second memory cell 11 after the value relating to the control of the memory circuit is recorded in the second memory cell 11. In this case, conventionally, control information, which needs to be supplied from outside of the memory circuit, is not required, therefore the storage circuit such as the flip-flop is not required, and the occupied area of the processor can be reduced. In addition, the control only on the memory circuit can be performed, and optimum control on the memory circuit can be performed.

Also, the control circuit 13 is capable of adjusting a delay of the input/output signal of the memory circuit by referring to the value in the second memory cell 11 after the value relating to the timing adjustment of the input/output signal to/from the memory circuit is recorded in the second memory cell 11. In this case, even when strict control is required for the control of the timings of set-up and hold between the processor and the memory circuit, such a requirement (strict control) can be eased, thus making it possible to increase the operation speed of the processor.

Also, the control circuit 13 is capable of correcting a signal delay within the memory circuit by referring to the value in the second memory cell 11 after the value relating to the timing adjustment of the input/output signal to/from the memory circuit is recorded in the second memory cell 11. In this case, a timing critical path within the memory circuit can be eased and drop of the power supply voltage due to concentration of current can be eased, thus making it possible to increase the operation speed of the memory circuit.

Also, when the cross talk suppressing circuit is provided within the memory circuit, the control circuit 13 is capable of controlling a capacity of the cross talk suppressing circuit within the memory circuit by referring to the value in the second memory cell 11 after the value relating to the cross talk suppression within the memory circuit is recorded in the second memory cell 11. In this case, when the cross talk suppressing circuit is not required, by lowering the aforementioned capacity, the operation speed of the memory circuit can be increased. Alternately, when the capacity of the cross talk suppressing circuit is deficient, by increasing the aforementioned capacity, an operation upper limit voltage of the memory circuit can be improved.

(Embodiment 3)

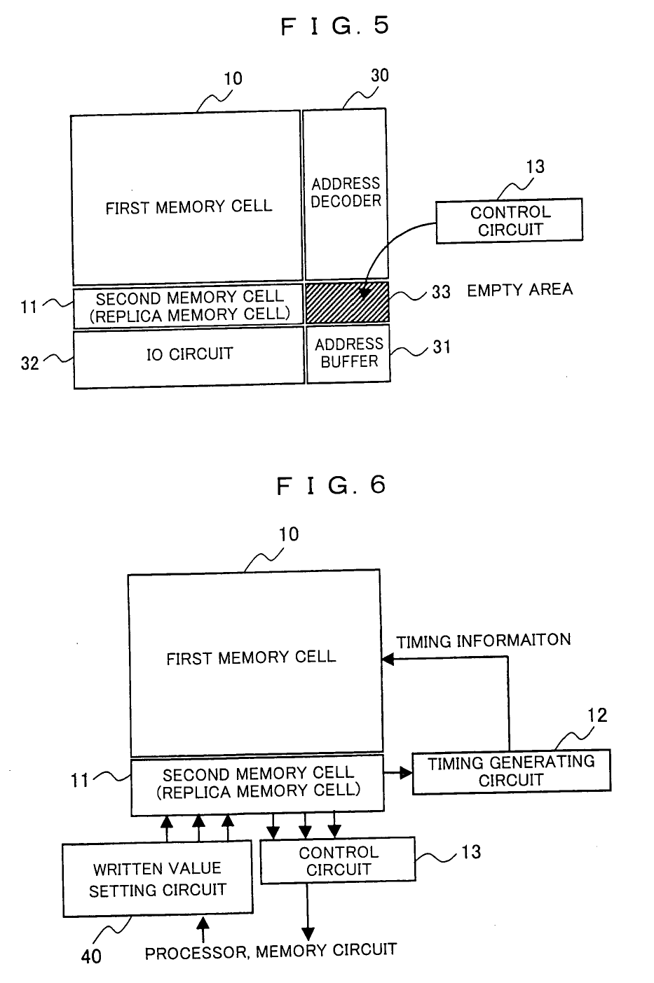

FIG. 5 is a block diagram showing a constitution of the memory circuit in an embodiment 3 of the present invention. The memory circuit shown in this figure includes the first memory cell 10, the second memory cell (replica memory cell) 11, an address decoder 30, an address buffer 31, and an 10 circuit 32. When the second memory cell 11 is used for a purpose of process compensation, peripheral circuits (such as a decoder) corresponding to the second memory cell 11 are not required. Therefore, as shown in a region marked with oblique lines in FIG. 5, an empty region 33 is generated adjacent to the second memory cell 11 in a region of the substrate on which the memory circuit is mounted. Further reduction of the circuit area can be realized by disposing the control circuit 13 in this empty region 33.

In the constitution of FIG. 1, when the memory circuit is multiported, a reading parts of one or a plurality of ports is used in a signal line connecting the second memory cell 11 and the timing generating circuit 12. However, the reading parts of the other ports are not used in the timing generation. In addition, in the constitution of FIG. 4, the reading part itself is not used. Accordingly, by using the bit lines of the reading parts, which are not used, as the signal lines to the control circuit 13 from the second memory cell 11, a new signal line needs not to be added, and further reduction of the circuit area can thereby be realized.

In the constitution of FIG. 1, it is also possible add a signal line connecting the second memory cell 11 and the control circuit 13 separately from the bit line of the reading part. For example, in the constitutions of FIG. 2 and FIG. 3, the DATA line and the NDATA line are directly connected to the control circuit 13. In this case, the circuit area is increased by an amount of the signal line thus added. However, by not using the reading part of the existent port, the control of the reading part can be performed independently of the existent port, and an easier design is realized. This contributes to the reduction of design man-hours.

In addition, when the value to be written in the second memory cell 11 is given from the processor, the written value setting circuit for setting the written value needs not to be provided in the memory circuit, and an easier design of the memory circuit is realized. Further, an arbitrary value can be given to the memory part of the second memory cell 11 from the processor, and therefore the number of states that can be used for control can be dramatically increased, compared to a case of giving a fixed value to the memory part of the second memory cell 11.

(Embodiment 4)

FIG. 6 is a block diagram showing a constitution of the memory circuit in an embodiment 4 of the present invention. By adding a written value setting circuit 40 for setting a written value in the second memory cell, an arbitrary value can be given to the memory part of the second memory cell 11 within the memory circuit. Thus, compared to a case of giving the fixed value to the memory part of the second memory cell 11, the number of states that can be used for control can be dramatically increased.

When the second memory cell 11 is used for a purpose of process compensation, particularly peripheral circuits (such as a decoder) corresponding to the second memory cell 11 are not required. Therefore, as shown in a region marked with oblique lines, an empty region 33 is generated adjacently to the second memory cell 11. By disposing the written value setting circuit 40 in this empty region 33, the circuit area can be further reduced.

In addition, when the value to be written in the second memory cell 11 in accordance with an internal state of the memory circuit is generated by the written value setting circuit 40, the written value needs not to be generated by the processor, and the load of the processor is thereby reduced. As the internal state, the operation speed of the memory circuit, an internal voltage, a cross talk amount of the signal line, etc, as will be described hereunder are given as examples. Further, by writing a control value suitable for the operation of the memory circuit in the second memory cell, self-correction control of the memory circuit can be performed.

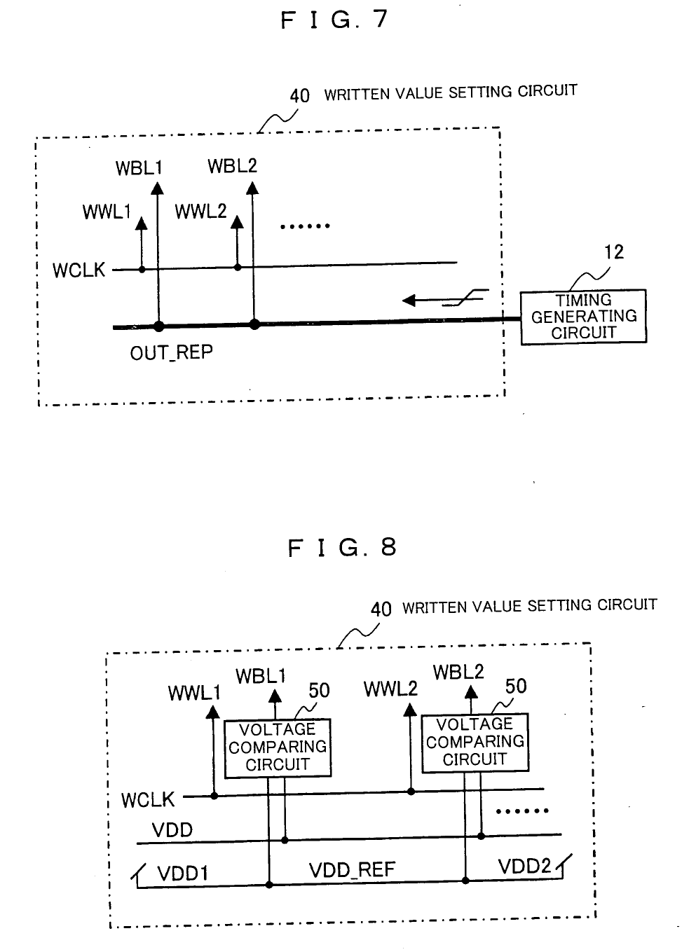

Moreover, when the control circuit 13 controls the power supply voltage and the substrate voltage of the memory circuit by referring to the value in the second memory cell 11 after the written value setting circuit 40 sets the value to be written in the second memory cell 11 in accordance with the operation speed of the memory circuit, a required operation speed can be realized by a minimum power. For example, as shown in FIG. 7, OUT_REP as an output of the timing generating circuit 12, whereby the reading operation speed is reflected, is supplied to write bit lines WBL1 and WBL2 of the second memory cell 11 as shown in FIG. 2 and FIG. 3 by using wiring of a large current capacity, and a writing clock WCLK to the second memory cell 11 is similarly supplied to write word lines WWL1 and WWL2. Thus, the written value in accordance with the operation speed can be given to the second memory cell 11.

Note that a VDD is a power supply line of the memory circuit, VDD1 and VDD2 are reference power supply voltages used for observing an internal voltage, and a VDD_REF is a reference power supply line used for observing the internal voltage.

In addition, when the control circuit 13 controls the power supply voltage and the substrate voltage of the memory circuit by referring to the value in the second memory cell 11 after the written value setting circuit 40 sets the value to be written in the second memory cell 11 in accordance with the internal voltage of the memory circuit, a voltage drop generated within the memory circuit can be compensated. As shown in FIG. 8, for example, such a written value setting circuit 40 is realized by the power supply line VDD of an internal voltage observation point, a comparing power supply line VDD_REF (connected to a first power supply voltage VDD1 and a second power supply voltage VDD2), and a voltage comparing circuit 50.

Also, when the control circuit 13 controls the cross talk suppressing circuit of the memory circuit by referring to the value in the second memory cell 11 after the written value setting circuit 40 sets the value to be written in the second memory cell 11 in accordance with the internal voltage of the memory circuit, the influence on the operation speed by the cross talk suppressing circuit can be reduced by reducing the capacity of the cross suppressing control circuit to an absolute necessary level.

Further, when the control circuit 13 controls the power supply voltage of the memory circuit by referring to the value in the second memory cell 11 after the written value setting circuit 40 sets the value to be written in the second memory cell 11 in accordance with the cross talk amount generated within the memory circuit, in a case of a large cross talk amount, the cross talk within the memory circuit can be reduced by lowering the power supply voltage.

Also, when the control circuit 13 controls the substrate voltage of the memory circuit by referring to the value in the second memory cell 11 after the written value setting circuit 40 sets the value to be written in the second memory cell 11 in accordance with the cross talk amount generated within the memory circuit, in a case of a large cross talk amount, the cross talk within the memory circuit can be reduced by applying the back bias.

Also, when the control circuit 13 controls the cross talk suppressing circuit of the memory circuit by referring to the value in the second memory cell 11 after the written value setting circuit 40 sets the value to be written in the second memory cell 11 in accordance with the amount of signal line noise within the memory circuit, in a case where the cross talk suppressing circuit is not required, the operation speed of the memory circuit can be increased by lowering the capacity. In addition, in a case where the capacity of the cross talk suppressing circuit is deficient, an operation upper limit voltage of the memory circuit can be improved by increasing the capacity.

Most preferable specific examples of the present invention have been explained in detail. However, combination and arrangement of components in the preferred embodiments can be variously changed without departing from the gist and scope of the following claims of the present invention.

What is claimed is:

1. A memory circuit, comprising:
a first memory cell mapped on an address space accessible from a processor;
a second memory cell not mapped on said address space; having a same constitution as that of said first memory cell; and
a control circuit for executing a control function relating to said memory circuit, wherein
an output signal line of said second memory cell is connected to said control circuit.

2. The memory circuit according to claim 1, further comprising a timing generating circuit, wherein
said control circuit executes a control function different from an access timing control executed by said timing generating circuit, and
said timing generating circuit generates an access timing to said first memory cell by referring to a value acquired from said second memory cell.

3. The memory circuit according to claim 1, wherein
said second memory cell is provided for compensating a characteristic fluctuation of said first memory cell.

4. The memory circuit according to claim 1, wherein
said second memory cell is provided for copying a load of a word line or a bit line connected to said first memory cell.

5. The memory circuit according to claim 1, wherein
a value relating to control of said processor is recorded in said second memory cell, and
said control circuit controls said processor by referring to the value in said second memory cell.

6. The memory circuit according to claim 1, wherein
a value relating to internal control of said memory circuit is recorded in said second memory cell, and
said control circuit performs internal control of said memory circuit by referring to the value in said second memory cell.

7. The memory circuit according to claim 1, wherein
a value relating to a power supply voltage of said memory circuit is recorded in said second memory cell, and
said control circuit controls the power supply voltage of said memory circuit by referring to the value in said second memory cell.

8. The memory circuit according to claim 1, wherein
a value relating to a substrate voltage of said memory circuit is recorded in said second memory cell, and
said control circuit controls the substrate voltage of said memory circuit by referring to the value in said second memory cell.

9. The memory circuit according to claim 5, wherein
a value relating to an operation frequency of said memory circuit is recorded in said second memory cell, and
said control circuit controls the operation frequency of said memory circuit by referring to the value in said second memory cell.

10. The memory circuit according to claim 6, wherein
a value relating to control of a port access of said memory circuit is recorded in said second memory cell, and
said control circuit controls the port access of said memory circuit by referring to the value in said second memory cell.

11. The memory circuit according to claim 6, wherein
a value relating to timing adjustment of an input/output signal to/from said memory circuit is recorded in said second memory cell, and
said control circuit performs the timing adjustment of the input/output signal to/from said memory circuit by referring to the value in said second memory cell.

12. The memory circuit according to claim 6, wherein
a value relating to timing correction of an internal signal of said memory circuit is recorded in said second memory cell, and
said control circuit performs the timing correction of the internal signal of said memory circuit by referring to the value in said second memory cell.

13. The memory circuit according to claim 6, further comprising a cross talk suppressing circuit for suppressing a cross talk within the memory circuit, wherein
a value relating to suppression of the cross talk within said memory circuit is recorded in said second memory cell; and
said control circuit controls said cross talk suppressing circuit by referring to the value in said second memory cell.

14. The memory circuit according to claim 1, wherein
said control circuit is disposed in an empty region close to said second memory cell within said memory circuit.

15. The memory circuit according to claim 1, wherein
said output signal line is constituted of a bit line of said memory circuit.

16. The memory circuit according to claim 1, wherein
said output signal line is constituted of a wire different from the bit line of said memory circuit.

17. The memory circuit according to claim 1, wherein
said processor sets a value to be written in said second memory cell.

18. The memory circuit according to claim 1, further comprising a written value setting circuit for setting a value to be written in said second memory cell.

19. The memory circuit according to claim 18, wherein
said written value setting circuit is disposed in an empty region close to said second memory cell within said memory circuit.

20. The memory circuit according to claim 18, wherein
said written value setting circuit sets said value based on an internal state of said memory circuit.

21. The memory circuit according to claim 20, wherein
said written value setting circuit sets said value based on an operation speed of said memory circuit.

22. The memory circuit according to claim 20, wherein
said written value setting circuit sets said value based on an internal voltage of said memory circuit.

23. The memory circuit according to claim 20, wherein
said written value setting circuit sets said value based on a cross talk amount of a signal line of said memory circuit.

24. A memory circuit, comprising:
a first memory cell mapped on an address space accessible from a processor;
a second memory cell not mapped on said address space and having a same constitution as that of said first memory cell;
a timing generating circuit for generating an access timing to said first memory cell by referring to a value acquired from said second memory cell; and
a control circuit for executing a control function different from an access timing control executed by said timing generating circuit, wherein
an output signal line of said second memory cell is connected to said control circuit.

25. A memory circuit, comprising:
a first memory cell mapped on an address space accessible from a processor;
a second memory cell not mapped on said address space, having a same constitution as that of said first memory cell and provided for compensating a characteristic fluctuation of said first memory cell; and
a control circuit for executing a control function relating to said memory circuit, wherein
an output signal line of said second memory cell is connected to said control circuit.
